(19) United States
(12) Patent Application Publication
(10) Pub. No.: US 2007/0200194 A1
(43) Pub. Date: Aug. 30, 2007

(54) Apparatus And Method For Temperature-Interrupting Protection Of An Electric Device

(76) Inventors: Alfons Graf, Kaufering (DE); Josef Hoeglauer, Muenchen (DE); Martin Schneider-Ramelow, Berlin (DE); Stefan Schmitz, Berlin (DE); Klaus-Dieter Lang, Berlin (DE)

Correspondence Address: BAKER BOTTS, L.L.P., 98 SAN JACINTO BLVD., SUITE 1500, AUSTIN, TX, 78701-4039, US

(21) Appl. No.: 11/680,342

(22) Filed: Feb. 28, 2007

(30) Foreign Application Priority Data
Feb. 28, 2006 (DE) 10 2006 009 236.8

(51) Int. Cl. H01L 31/058

(52) U.S. Cl. 257/469

(57) ABSTRACT

A current load of an electric device having a current inlet or current outlet can be protected cost-effectively and efficiently via a contact pad in the current inlet or current outlet when a first conductive material and the second conductive material are connected conductively in the contact pad such that the first conductive material and the second conductive material can form an eutectic mixture which has a fusion temperature below the fusion temperature of the individual materials and when the contact pad is additionally implemented such that the conductive connection between the first and second materials is interrupted when a fused eutectic mixture occurs.

### RELATED APPLICATION

This application claims priority from German Patent Application No. DE 10 2006 009 236.8, which was filed on Feb. 28, 2006, and is incorporated herein by reference in its entirety.

### TECHNICAL FIELD

The present invention relates to the protection of an electric device, and in particular to a concept for providing a contact pad in a device that can serve as thermal protection of the device.

### BACKGROUND

A task that is becoming more and more important in the field of electronics, particular under safety aspects, is how individual devices or circuit parts can be shut down specifically, permanently and as inexpensively as possible in case of error in order to avoid large consequential damage. Thus, for example, power semiconductors are nowadays used on a large scale for switching electric loads, such as lamps, valves, motors, heating elements, etc., and above that they are increasingly used in the field of power management for switching off individual circuit parts, for example to reduce the energy consumption of battery-operated devices.

The two typical arrangements of a switch and a current load are illustrated in FIG. 7. A supply voltage terminal 2, a fuse 4, a current-consuming load 6 and a power switch 8 are shown in FIG. 7. The fuse 4, the load 6 and the power switch 8 are connected in series between the supply voltage terminal 2 and ground along a current flow direction 10. Depending on whether the power switch 8 along the current flow direction 10 lies closer to the supply voltage terminal 2 than the load 6, this is referred to as a high-side or a low-side switch, wherein a high-side switch is when the power switch 8 along the current flow direction 10 is arranged closer to the supply voltage terminal 2 than the load 6. In order that only a low power dissipation is generated in the power switch 8, it is important that the power switch 8 has a much lower electric resistance in the ON state than the load 6. For low-voltage applications, electronic power MOSFETs have mostly gained acceptance as electronic switches. The extremely fast development towards lower and lower specific forward resistances (RDS(on)×A) over the past years has allowed that today currents of many amperes can be handled with semiconductor switches arranged directly on a circuit board and without specific cooling measures.

A further important problem area includes erroneous devices lying directly at the supply voltage. These include devices that become low-resistive at the end of their life span, at overload or at premature breakdown with high probability. This concerns particularly varistors, multi-layer ceramic capacitors (MLCC) and tantalum electrolytic capacitors, as are illustrated in FIG. 8. FIG. 8 shows a selection of such problematic devices that are protected by a common fuse. A supply voltage terminal 20, a fuse 22, a plug connector or cable terminal 24, respectively, a varistor 26, a multi-layer ceramic capacitor 28 and a tantalum electrolytic capacitor 30 are shown. The fuse 22 and the plug connection 24 are connected in series between the supply voltage terminal 20 and a switching node 32. The varistor 26, the multi-layer ceramic capacitor 28 and the tantalum electrolytic capacitor 30 are connected in parallel between the circuit node 32 and ground. In the functional state, the multi-layer ceramic capacitor 28, the tantalum electrolytic capacitor 30, the varistor 26 and also the plug connection 24 have a negligible leakage current and thus a negligible static power dissipation in the whole allowable operation voltage and operating temperature range. However, if the leakage current increases in the error case, or if a short circuit between plates occurs, specifically in multi-layer ceramic capacitors, for example due to a break caused by a mechanical stress, the static power dissipation rises extremely and can cause extreme overheating of a device, since now a high current flow through the device becomes possible. Plug connections or cable terminals 24 lying in the circuit are also safety-critical when these normally very low-resistive elements become higher-resistive, for example by contamination or age, so that the power dissipation and thus the temperature in these devices can rise far above the allowable measure. A problem can also occur when the otherwise high-resistive plug connector between contact A and contact B becomes low-resistive due to contamination or aging and thus a leakage current flows.

The problem of high local rise of the operating temperature occurs also for a power switch as shown in FIG. 7. One problem occurs when no complete switching on or off is performed or possible due to errors or destruction in the semiconductor switch or its control. Then, the switch reaches neither its low nominal forward resistance nor its high-resistive OFF state. Thus, the power dissipation in the switch increases greatly. In the worst case of power adaptation, i.e. when the forward resistance of the switch reaches the range of the value of the load resistance, the power dissipation in the switch can rise up to a quarter of the load nominal power, with non-linear loads, such as incandescent lamps, to even higher values. This will be illustrated in more detail below based on an example. In a power MOSFET with a forward resistance of 10 mΩ, which is used as a switch for a load of 120 W at 12 V, a power dissipation of 1 W results in nominal operation. The cooling of the MOSFET will be configured for this power dissipation in a specific circuit. If, however, the forward resistance rises due to an error (e.g. in the control), the power dissipation in the switch can reach values of up to 30 W when in the error case, the forward resistance of the power MOSFET has the same amount as the ohmic resistance of the load. In a cooling configured for 1 W, this very quickly causes dangerously high temperatures up to a fire hazard, for example of the circuit board.

For protection against damages by too large currents, mostly current-triggered fuses are used, wherein the same are available in the most diverse structures and trigger characteristics. The common current-triggered fuses cannot level out an error case of a power switch 8, as described above, since no overcurrent occurs in the switch in FIG. 7. The load 6 limits the current always to a value that does not exceed the nominal operation current, so that the power dissipation occurring at the fuse 4 is too low to fuse the material of the fuse and to interrupt the circuit. Even for larger and centrally protected assemblies, as illustrated, for example, in FIG. 8, exists the problem that the current occurring in an error case, for example, at the multi-layer ceramic capacitor 28 is, on the one hand sufficient to generate an extreme excess temperature locally at the multi-layer ceramic capacitor 28, but on the other hand, the current does not reach a value high enough to trigger a centrally disposed fuse 22. Apart from fuses, positive temperature coefficient resistors (PTC) based on ceramic or polymer (e.g. PolySwitch™) are widely used as overcurrent protection. If, however, no overcurrent occurs, as in the above-described error case, these fuses will also be unsuitable as protection elements. Due to their size, the high costs and particularly the trigger characteristics, positive temperature coefficient resistors are not suitable for protecting many safety-critical devices.

In capacitors, the operating alternating current (ripple current) can lie significantly above the required trigger direct current, and then protection with a PTC element and a classical fuse is basically not possible. PTC elements placed specially very close to the device to be protected would basically fulfill the task of interrupting a current flow at a very high local temperature rise, but for most applications these elements are not low-resistive enough or too expensive, respectively.

A temperature switch (e.g. a bimetal switch) can also be used for protection against overheating, but the same are too bulky for usage on modern SMD-loaded assemblies and are too expensive for protecting every individual safety-critical device. Special temperature-triggered circuit breakers are used, for example, in coffee machines or irons. In the special temperature-triggered circuit breakers, two current contacts assembled under mechanical bias are triggered from their biased position by fusing a fuse material, whereby the contacts become spatially separated by triggering the contacts. Due to this construction principle, the special temperature-triggered circuit breakers are too bulky for usage in modern assemblies.

Apart from that, temperature sensors are used for protecting circuits against excess temperature, wherein this type of monitoring achieves no protection function for the above-described error scenarios of a safety-critical device by. The mere detection of an excess temperature at a no longer controllable semiconductor switch is useless, since the current flow can no longer be interrupted by interfering with the control voltage of the defective switch.

A further possibility for monitoring switches is the usage of a crowbar switch, wherein a crowbar switch is a powerful short-circuit switch, which is able to trigger an existing central fuse by short-circuiting the current path to ground, thus causing a current flow in the switch which is high enough to fuse a fuse. However, due to the high costs and the space requirements, crowbar solutions are not suitable for distributed protection measures where a plurality of safety-critical devices are to be protected individually. A centrally disposed crowbar switch significantly limits the possible fields of usage, since in many cases it is not tolerable to shut down the overall system in the case of an error instead of, for example, only one individual load current path.

The respective protection solutions in the prior art are cost-intensive and bulky. This means that they normally require an additional attachment of a safety element or a discrete device, respectively, in a circuit layout, which causes a significant increase of space requirements, particularly in the case where individual devices are to be protected individually against overheating.

The unpublished German patent application 10200504321 describes how an electric device can be protected in a temperature-triggered way when a suitable fuse material is used and when a close thermal coupling exists between the load of the device to be protected and the fusible material.

The unpublished German patent application 10200504321 describes that triggering a fuse of an appropriate material can be advantageously improved when appropriate structural measures are taken, such as structurally generated cavities which are in the immediate vicinity of the fusing material, so that a fused material can flow into such a cavity.

The unpublished German patent application 102005024321.5 describes how an electronic power device can be protected against overheating via a protection element when a protection element is disposed in close thermal coupling to the power device to be protected.

The German patent application 10334433A1 describes a current-interrupting fuse in the supply line of a semiconductor elements where a current flow can be interrupted via a fusible material (eutectic) integrated in the device, when a limiting temperature is exceeded.

### SUMMARY

According to an embodiment, the an electric device having a temperature-interrupting current inlet is provided and may have: a current load having a current inlet or outlet; a contact pad in the current inlet or outlet, having: a first terminal area of a first conductive material; and a second terminal area of a second conductive material differing from the first material, wherein the first and second materials are conductively connected to each other at a contact region, wherein the first and second materials are selected such that they can form an eutectic mixture having a fusion temperature below a fusion temperature of the first and second materials, and which depends on an operating state of the current load to be protected; and wherein the contact pad is implemented such that a current flow is established through a contact area between the first and second materials, so that the conductive connection between the first and second terminal areas is interrupted by the occurrence and flow of a fusible eutectic mixture.

### BRIEF DESCRIPTION OF THE DRAWINGS

Other objects and features will become clear from the following description taken in conjunction with the accompanying drawings, in which:

FIG. 1A to 1C show the forming of a fusible eutectic between an aluminum bonding wire and zinc die;

FIG. 2 shows the separation effect of a contact pad in the semiconductor device;

FIG. 3 shows a current-interrupting cavity;

FIG. 4 shows a crack formation in the semiconductor housing;

FIG. 5 shows a crack formation at the interface between bonding wire and semiconductor contact;

FIG. 5B shows an embodiment;

FIGS. 6A and 6B show contacts between chip and leadframe;

FIG. 7 shows devices to be protected in high-side and low-side configuration; and

FIG. 8 shows further safety-critical devices.

### DETAILED DESCRIPTION

According to another embodiment, an electric device for temperature-dependent interruption of a current inlet is provided and may have: a contact pad in the current inlet or outlet, having: a first terminal area of a first conductive material; and a second terminal area of a second conductive material differing from the first material, wherein the first material and the second material are conductively connected at a contact region, wherein the first material and the second material are selected such that they can form an eutectic mixture having a fusion temperature below a fusion temperature of the first and second materials, and which depends on an operating state of the current load to be protected; and wherein the contact pad is implemented such that a current flow is established through a contact area between the first material and the second material, so that the conductive connection between the first and the second terminal area is interrupted by the occurrence and flow of a fused eutectic mixture.

According to another embodiment, a method for producing an electric device having a temperature-interrupting current inlet may have the steps of: providing a first conductive material; providing a second conductive material differing from the first material, wherein the first and second materials are selected such that they can form an eutectic mixture having a fusion temperature below the fusion temperature of the first and second materials and depending on an operating state of the current load to be protected; producing a contact pad in a current inlet or current outlet of a current load of the device, wherein the contact pad is implemented such that a current flow through a contact area between the first material and the second material is established, so that a conductive connection between a first terminal area of the first conductive material and a second terminal area of the second conductive material is interrupted during the occurrence and flow of a fused eutectic mixture.

Thereby, a current load of an electric device having a current inlet or a current outlet, can be protected cost-effectively and efficiently via a contact pad which lies in the current inlet or current outlet when a first conductive material and a second conductive material are connected conductively in the contact pad such that the first conductive material and the second conductive material can form an eutectic mixture having a fusion temperature below the fusion temperature of the individual materials, and when above that the contact pad is designed such that the conductive connection between the first and the second material is interrupted when a fusible eutectic mixture occurs.

In a first embodiment, the concept can be realized in an electric device comprising a current load having a current inlet and a current outlet. Thereby, a contact pad can be integrated in the current inlet or the current outlet, respectively. At the contact pad, a first material can be connected conductively to a second material, wherein the first and the second material are selected specifically for the desired protection effect, since a mixture of the first and the second material can form an eutectic with a specific fusion temperature.

Protecting the current load within the electric device is based on the fact that, when the fusion temperature of the eutectic is exceeded, an eutectic mixture forming at the contact pad of the first and the second material begins to fuse. The contact pad is structured such that a conductive connection between the first and the second material is interrupted when the fusible eutectic occurs. Thereby, the contact pad can be produced by diverse connection methods between the first and second materials. A contact on an atomic level is important, such as can be produced, for example, by conventional or ultrasonic bonding, squeezing or crimping. When the fusion temperature of the eutectic is exceeded, the conductive connection is interrupted, wherein the temperature-triggered fuse can be generated in a cost-effective way merely by combining suitable materials. This has the great advantage that the trigger temperature of the fuse can be individually adapted to the protection requirements of the current load by selecting different material combinations. Thereby it is an additional advantage that both a current-triggered fuse and a purely temperature-triggered fuse can be realized by this concept. In the case of the current-triggered fuse, this means that an electric device can be constructed such that an erroneous current caused by a malfunction of the current load causes an increased power dissipation in the contact pad, which causes the locally generated excess temperature required for generating the fusible eutectic. Thus, this corresponds substantially to the concept of a classical current fuse with the great advantage that the protection function for the current load is directly implemented in the electric device.

A further possibility is the generation of a pure temperature fuse, where the current load and the contact pad are closely thermally coupled, so that during a malfunction of the current load, excessively produced heat rises the temperature at the contact pad so much that the formation of the fusible eutectic is triggered. Thereby, again, the geometrical form of the device can be advantageously considered in that, for example with worse thermal coupling, materials whose eutectic mixture has a lower fusion point are used.

Both in the case of current-triggered and in the case of temperature-triggered design according to different embodiments, the advantage results that an electric device is protected automatically in a printed circuit board without requiring additional measures or devices, respectively.

Eutectic mixtures that are particularly useful for protection have fusion temperatures of 200° C. and 500° C.

A further advantage is that the protection function can be obtain merely by bringing two suitable materials in contact with each other, wherein preferably standard production methods are used for connecting the two materials. Thereby, the protection function in an electric device can be generated without having to significantly change the production method or having to implement new construction steps or structural features into an electric device.

According to an embodiment, the contact region is designed geometrically such that the current flow through the contact region has to be established through a contact area between the first material and the second material (which means through the area where the materials abut) so that a conductive connection between the first and the second terminal area is interrupted when a flowable fusible eutectic mixture occurs. Compared to the prior art, this has the great advantage that only very little material has to be fused for interrupting the current flow since the fusible eutectic has to be formed only immediately at the contact pad. Thus, fusing and separating the current flow, is possible with significantly less energy consumption than before and thus more efficiently (faster and more reliable separation) compared to the corresponding apparatuses and methods of the prior art.

In a further embodiment, the current load is, for example, a chip, which is mounted on a chip island in a housing, wherein the electric connection of the chip to a leadframe or to another chip holder is made by bonding wires. For integrating the protection functionality, the bonding wire is generated from the first material and a connection pad of the chip or a connection pad of the leadframe or the chipholder, respectively, of a second material, so that the protection function results automatically when bonding at the contact pads. One embodiment is particularly advantageous, where the bonding wire consists of aluminum and where the contact pad on the chip or the leadframe consists at least partly of zinc, so that a transition from aluminum to zinc results during contacting, wherein a zinc-aluminum mixture has a fusion temperature of 382°, which allows a protection of the chip and the circuit board surrounding the chip against overheating. A particular advantage of an implementation with aluminum bonding wires is that bonding with aluminum wires is a standard method and the implementation can thus be made easily, since the bonding or the bonding machines, respectively, do not have to be altered or adapted. If additional deposition of a zinc layer on a contact pad of the chip or the leadframe is required, this is also possible without high additional overhead.

In a further embodiment, the contact pad is structured or geometrically formed such that when the fusible eutectic mixture occurs, the electrically conductive connection between the first material and the second material is interrupted and that when the eutectic mixture is solidified again, the electrically conductive connection is reestablished. Thereby, an electric device can be reversibly protected against excess temperature or overcurrent, so that the device can be used again after triggering the temperature protection once when the error situation, i.e. the overcurrent or the excess temperature, has disappeared.

In a further embodiment, the contact pad is surrounded by a cast material, such as is common, for example, with chips that are in contact with the leadframe via bonding. On the one hand, this is advantageous since in this case materials having no high mechanical strength can be used for bonding or as material of a contact pad, since the mechanical stability of the arrangement and the contact is ensured by the surrounding cast fluid (molding compound). Thereby, for example, brittle materials can be used, which further increases the selection of possible material combinations and thus allows adapting the protection function of the contact pad more exactly to the current load or the error scenario, respectively.

Apart from that, the appropriate selection of the molding compound can contribute to further improving the desired trigger behavior of the contact pad. Thus, a molding compound or cast material, respectively, which forms cracks under the influence of heat supports the triggering of the fuse or the trigger speed, respectively, since a fusible eutectic is then sucked into the formed cracks under the influence of the capillary effect or can flow into the cracks, respectively. Thereby, disconnecting the fuse is accelerated or irreversible disconnection is enabled. In a reversible implementation of the protection function of the contact pad, a cast compound is used that shows no crack forming, so that the material compound is not sucked in in a capillary and irreversible way by possibly occurring cavities during the first fusion.

In a further embodiment, an alloy of, for example, 97.5Pb2.5Ag is integrated in a conventional semiconductor casing surrounded with molding compound which has a fusion point of 303° C. This alloy can be implemented in any form, such as a wire, die or ribbon, and is primarily used as a metallic connection. Thereby, both bond connections between chip and leadframe, but also connections between two chips or between two leadframe terminals can be realized. Thereby, the alloy can produce a punctual connection, such as in the currently common bonding wire, but it can also produce a large-scale connection in the form of a die. The respective conductive contacting can thereby be produced via conductive adhesive or other common contacting methods, such as soldering, welding or ultrasonic bonding.

It is shown that merely fusing the alloy in the molding compound is sufficient for interrupting the current flow. Thereby, first, a fusible channel occurs at the position where the bonding connection produced from the alloy was embedded in the molding compound. Due to the heat influencing the fusion of the alloy, smaller or bigger cracks are formed in the molding material as well as at the boundary layers between the leadframe, the chip areas and the molding material, and gaps are formed at the boundary layers. Possible volume extensions during the fusion process or the degassing or mechanical tensions, respectively, additionally cause or support this formation of cracks. The fusible alloy is partly or almost completely sucked into those cracks and gaps by a capillary action. Thereby, an empty channel freed from form alloy material is formed at the original position of the connection die (the contact pad) so that the current flow between chip and leadframe is interrupted. Thereby, it is of no importance whether the temperature rise is caused by the external heat supply (heating plate) or the internal heat supply (heating by current flow).

In a further embodiment, an AL thick wire bonding is produced on zinc in a semiconductor housing surrounded by molding compound. A simple possibility for realizing this is disposing the bond connection on a thin zinc layer, which is deposited on the chip surface or on the leadframe surface. Thereby, a zinc layer can also be deposited on other components, which are connected via bonding wires. A further possibility is to deposit a zinc layer afterwards as zinc dies or a zinc mold on the leadframe or the chip, respectively, for realizing this concept. The connection AL-Zn can, of course, assume any form, for example also as a die with an appropriate eutectic mixture ratio. Thereby, other material combinations are also possible. Examples for possible materials are illustrated in the following list together with fusion points of the eutectic mixture that can be generated from the same.

| Alloy | Fusion point [° C.] |
|---|---|
| 82.6 Cs, 17.4 Zn | 266 |
| 80 Au, 20 Sn | 280 |
| 97.5 Pb, 2.5 Ag | 303 |
| 96 Pb, 2.5 Ag, 1.5 Sn | 304 |
| 88 Au, 12 Ge | 356 |
| 96.4 Au, 3.6 Si | 370 |
| 95 Zn, 5 Al | 382 |

Both bond connections between the chip and the leadframe, but also bond connections between two chips or between two leadframe terminals can be realized from the different materials.

If a bond connection is produced, for example, from aluminum wire in connection with a zinc contact in a typical semiconductor housing, exceeding the eutectic temperature (in the case of Al—Zn approx. 383° C.) is sufficient to interrupt the current flow after a certain reaction time. Thereby, a gap or cavity, respectively, occurs at the position of the aluminum-zinc contact by heat impact and fusing, whereby the current flow is interrupted. Thereby, on the one hand, Zn in the Al wire dissolves, whereby a cavity can be formed. Additionally, as has already been described above, the fluid fusion is sucked in a capillary way into the cracks in the molding material or in cavity-forming boundary layers between molding compound and leadframe or chip, respectively. Thereby, it is insignificant whether the temperature rise is caused by an external or an internal heat supply.

In the following list, the advantageous characteristics and implementations will be summarized briefly:
Fusible metal or alloy, e.g. 97.5Pb2.5Ag as an electrically conductive connection in a semiconductor housing or in a passive device (capacitor, plug)
Atomic contact of two materials that can form a fusible eutectic, such as zinc-aluminum bonding, in a semiconductor housing or in a passive device (capacitor, plug)
Zinc can be deposited as a thin or a thick layer on the chip, the leadframe or another surface to be contacted, and a deposition on both sides is also possible.
Zinc can be introduced between the surface to be contacted and an Al-counter-contact in the form of a die.
The arrangement of zinc and aluminum is basically interchangeable.
Both structures serve for producing an electric connection and also as a thermally triggered current interruption.
Advantageous fusion temperatures are in the range between 270 and 400° C.
Crack formation at surrounding materials (molding material) by impact of heat and/or volume change and/or fusing the standard chip-leadframe solder connection with subsequent capillary effect
Gaps at material boundary layers forming by the impact of heat and/or volume change and/or fusing the standard chip-leadframe solder connection with subsequent capillary effect
The current interruption is established by the drift of the liquid conductive connection materials.
The current interruption can be channel- or pin-selective or device-selective.
The current interruption can be implemented reversibly or preferably irreversibly with regard to temperature or can represent a combination of both possibilities.
The current interruption can exist several times in the device, and triggering can be performed in multiple stages at different temperature thresholds.
The current interruption can also be implemented without a chip, i.e. as a purely passive fuse in a semiconductor housing, e.g. as a protection element for other devices or it can be implemented as an individual protection device.
The application of the current interruption between the chip-leadframe, chip-chip, leadframe-leadframe (instead of the chip, a passive device (e.g. chip capacitor) can be introduced)
The current-interrupting effect can have any form: wire, ribbon or die.
The impact of heat can be established both from the inside and from the outside of the device.
Contacting the fusible alloy, e.g. 97.5Pb2.5Ag with a chip or a leadframe is performed via conventional methods: soldering, welding, adhering or bonding.

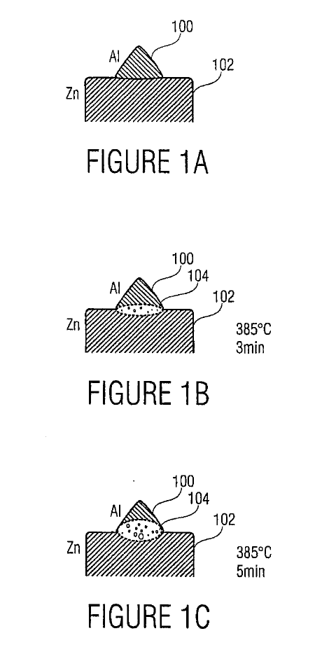

FIGS. 1A to 1C show the gradual formation of the fusible eutectic at an interface between a bonding wire and a contact pad, wherein the bonding wire and the contact pad are selected from appropriate materials.

A bonding wire 100 of aluminum is illustrated, which is bonded on a contact die 102 of zinc, wherein aluminum and zinc form an eutectic mixture with a fusion point of approximately 382° C. at a mixture ratio of approximately 95% zinc and 5% aluminum. The original situation is illustrated in FIG. 1A, the situation after the effect of a temperature of 385° C. for a period of approx. 3 minutes in FIG. 1B, and the situation after the impact of a temperature of 385° C. after 5 minutes in FIG. 1C.

As can be seen in FIG. 1B, a fusion area 104, wherein a fusible eutectic mixture has formed, is formed already after approximately 3 minutes at a temperature that is only slightly higher than the melting temperature of the eutectic mixture, wherein cavities obstructing the current flow through the contact pad have been formed by volume changes during the fusion process or by leaking of the fusible material, respectively. Additionally, a volume change is caused in that zinc dissolves in the aluminum wire.

As can be seen in FIG. 1C, the fusion area 104 has extended further after 5 minutes and several cavities are formed so that the electrically conductive contact is already almost completely interrupted in the situation in FIG. 1C.

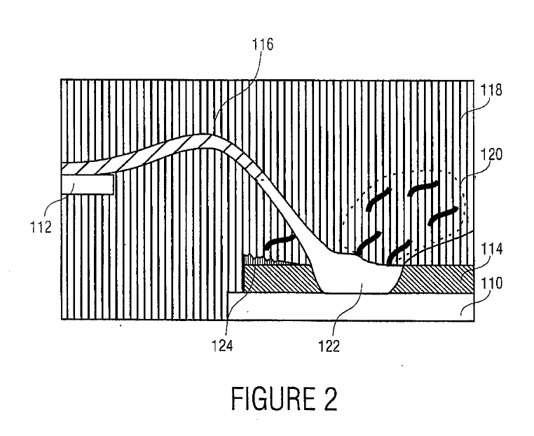

FIG. 2 shows a situation as it occurs after triggering a contact pad within a semiconductor housing. FIG. 2 shows a contact of a leadframe 110, a contact of a chip 112, a zinc-plated area 114 on the contact of the leadframe and unfused residues of a bonding wire of aluminum 116. As it is common with semiconductor chips, the bonding and the chip are cast in a cast or molding compound 118 to ensure mechanical protection of the chip.

A plurality of cracks has formed in the molding compound 118 in a crack area 120 by the impact of the temperature, into which parts of the fusible eutectic of aluminum and zinc have flown, so that a cavity 122 is formed at a location that was originally filled by zinc and bonding wire. Apart from that, an occurring crack formation between the molding compound 118 and the zinc-plated area 114 is shown in FIG. 2, as it frequently occurs, wherein additional fusible material can flow into the crack area 124, which causes a further enlargement of the cavity 122.

When the first material, of which a bonding wire consists, and a second material, of which a terminal area is formed, are appropriately chosen, the formation of a cavity 122 is favored by fusing an eutectic that has been formed in the contact area of the bonding wire and the contact area by the above-described mechanisms, so that the current flow to a current load, which means a chip with a terminal 112, is interrupted.

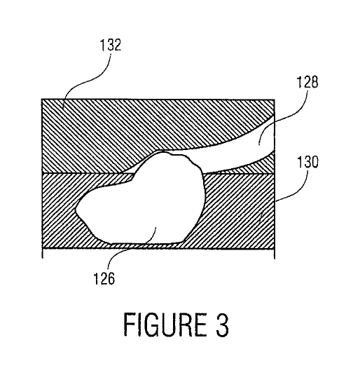

FIG. 3 shows enlarged the formation of a cavity 126 at a contact pad between a bonding wire 128 of an appropriately selected first material and a contact die 130 of an appropriately selected second material. In the configuration shown in FIG. 3, a fusible eutectic has flown into cracks or gap areas between the contact die 130 and a molding material 132, so that the electrically conductive connection is interrupted by the cavity 126.

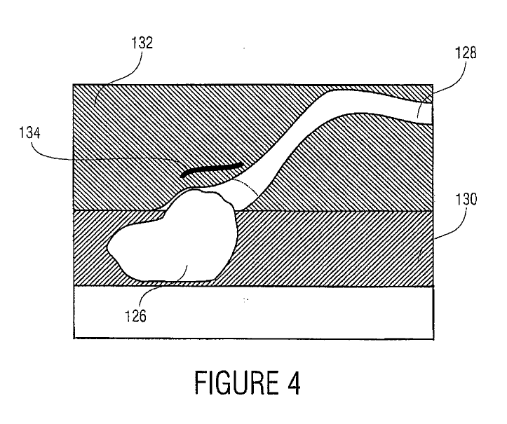

FIG. 4 shows the situation of FIG. 3 in a larger scale, so that additionally the formation of a crack 134 in the molding compound 132 can be seen, which was induced by the temperature rise. The formation of the crack can be helped by occurring volume changes of a fusible eutectic or by mechanical or thermal tensions, respectively, as well as by degassing, or by decomposition of the molding compound, respectively.

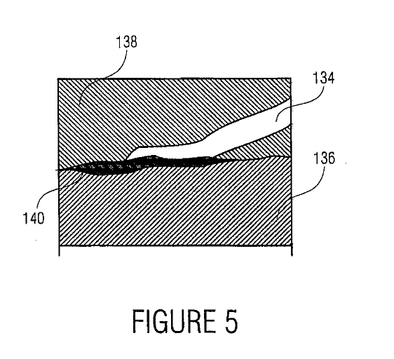

FIG. 5 shows a further scenario that can cause an interruption of a current flow in a contact. A bonding wire 134 of a first suitable material and a contact die 136 of a second suitable material are illustrated, wherein the contact pad formed between the bonding wire 134 and the contact die 136 is cast into a molding compound 138.

An eutectic fusible mixture has formed at the interface between the bonding wire 134 and the contact die 136, which has flown from the interface, so that a gap 140 interrupting the current flow has been formed.

FIG. 5B shows an embodiment showing its advantageous geometrical structure of the first terminal and the second terminal area.

FIG. 5B shows a current load 150, a first current terminal 152, a second current terminal 154, a first terminal area 156 and a second terminal area 158. The current load 150, that can, for example, be a resistor or any other power-consuming device, is connected to ground and to the second current terminal 154. Thereby, the geometrical arrangement is such that the current through the current load 150 flows both through the first current terminal 152 and through the second current terminal 154. The first contact area 156 consists of a first material, and a second contact area 158 consists of a second material, which can together form an eutectic mixture. In a contact area 162, the first terminal area 156 and the second terminal area 158 are conductively connected such that they form a common contact area 160. As can be seen in FIG. 5B, the geometrical arrangement of the terminal area is such that a current for a current inlet of the current load 150 has to flow through the contact area. This has the great advantage that for interrupting the current inlet a fusible eutectic mixture has to be formed merely in the area of the contact area 160. This requires only a low energy supply and thus fast triggering of the protection function, since the material has to be fused only in the immediate area around the contact area 160 within the contact region 162 to obtain complete interruption of the current inlet.

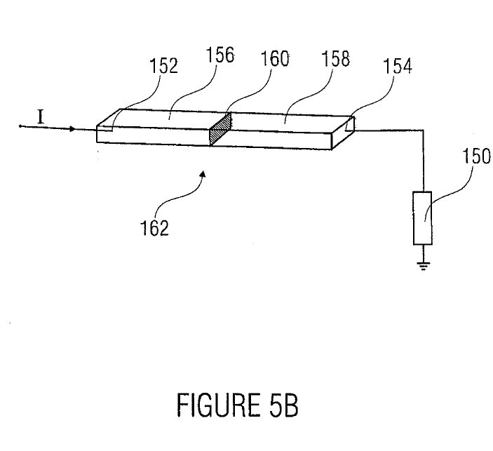

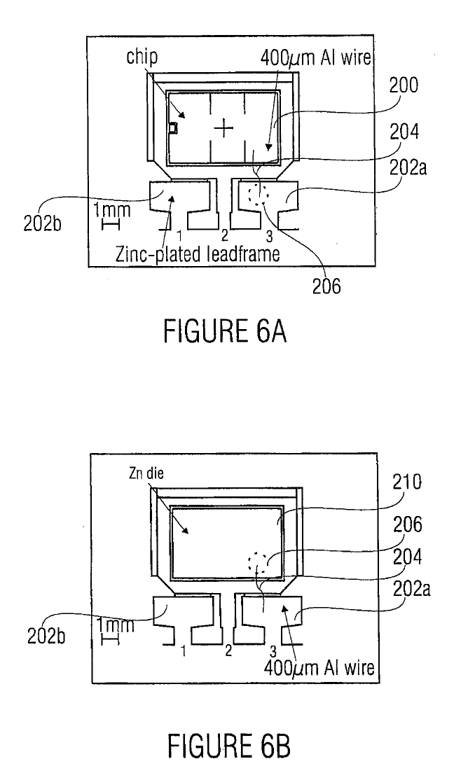

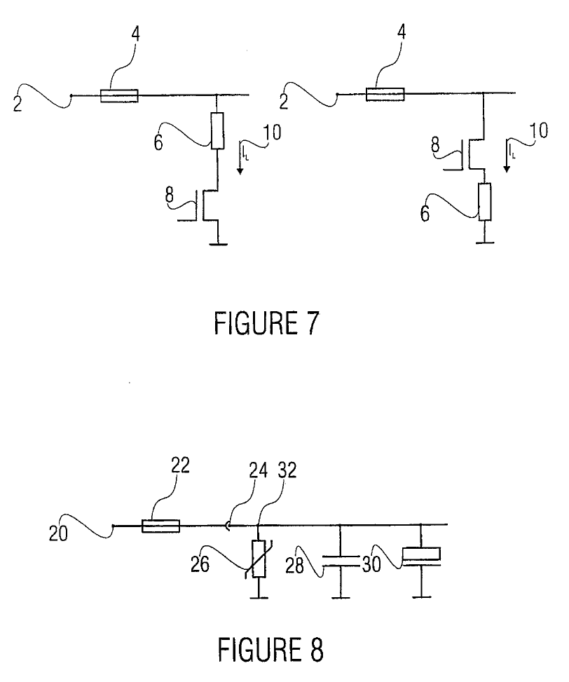

FIGS. 6A and 6B show the connection of a chip to a leadframe, wherein the concept for protection is realized. FIG. 6A shows the contact region 200 of a chip and a first contact region 202A and a second contact region 202B of a leadframe, wherein the contact region 200 is to be electrically connected to the contact region of the leadframe 202A in a chip housing. According to an embodiment, the electrical connection is made via a bonding wire 204 of aluminum, so that a contact pad exists between a first material (aluminum) and a second material (zinc) on the contact region 202A of the leadframe. Thereby, an eutectic mixture of aluminum and zinc can form in the contact region 206.

The embodiment shown in FIG. 6A has the great advantage that bonding with aluminum wires is widely used, so that a housed chip with a temperature-interrupting current inlet can be produced with only low production overhead by zinc-plating the contact regions of the leadframe. Thereby, the concept can be easily and efficiently integrated into standardized production methods.

FIG. 6B shows the situation of FIG. 6A, wherein in the case shown in FIG. 6B the contact regions 202A and 202B are not zinc-plated. Instead, a deposited zinc die 210 is on the terminal area of the chip, so that the contact area 206 is formed by the aluminum bonding wire 204 and the zinc die 210. Like in the embodiment shown in FIG. 6A, a later conversion of a production line is possible without large effort, since merely a zinc die has to be deposited on the contact pads on the chip as the current load to be protected.

While the above-described discussions have mainly been related to the application of the concept in a semiconductor device, the concept can also be applied to other areas, for example passive devices. In capacitors and plug connectors, the terminals or internally conductive connections can be produced with a fusion alloy or with a combination of first and the second materials, which can form an eutectic. Thus, even for passive devices, a current interruption may be realized after a strong impact of heat. In a capacitor, the terminal pin, with which the capacitor is soldered to a printed circuit board, can consist, for example, of the first material, while the contact connecting the terminal pin with the actual capacity within the housing can consist of the second material, so that the concept can be realized by a contact pad, which is within the housing of the capacitor.

While in the embodiments the contact between the first material and the second material is mostly produced by bonding, any other way of establishing atomic contact between the first and second materials is also suitable for implementing the concept. In that context, additionally, an influence of the molding compound can be positive, which can additionally stabilize a possibly mechanically instable connection between first and second materials, so that the concept can also be realized with material combinations that would otherwise not be suitable due to their mechanical characteristics.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. An electric device having a temperature-interrupting current inlet, comprising:
a current load having a current inlet or outlet;
a contact pad in the current inlet or outlet, comprising:
a first terminal area of a first conductive material; and
a second terminal area of a second conductive material differing from the first material,
wherein the first and second materials are conductively connected to each other at a contact region, wherein the first and second materials are selected such that they can form an eutectic mixture having a fusion temperature below a fusion temperature of the first and second materials, and which depends on an operating state of the current load to be protected; and
wherein the contact pad is implemented such that a current flow is established through a contact area between the first and second materials, so that the conductive connection between the first and second terminal areas is interrupted by the occurrence and flow of a fusible eutectic mixture.

2. The electric device according to claim 1, wherein the contact area is implemented such that when separating the first and second materials along the contact area, the current flow between the first terminal area and the second terminal area is interrupted.

3. The electric device according to claim 1, wherein the first and second materials are selected such that the fusion temperature of the eutectic mixture is higher than the temperature caused by a power dissipation in the contact area, when the current load is in a normal operating state; and
that the fusion temperature of the eutectic mixture is lower than the temperature caused by the power dissipation in the contact region, when the current load is in an operating state to be protected.

4. The electric device according to claim 1, wherein the current load and the contact region are thermally coupled to each other, and wherein the first and second materials are selected such
that the fusion temperature of the eutectic mixture is higher than the temperature in the contact region caused by the current load, when the current load is in a normal operating state; and
that the fusion temperature of the eutectic mixture is lower than the temperature in the contact region caused by the current load, when the current load is in an operating state to be protected.

5. The electric device according to claim 1, wherein the fusion temperature of the eutectic mixture lies between 200° C. and 500° C.

6. The electric device according to claim 1, wherein the current load is a chip, wherein the contact pad is formed by a bonding wire of the first conductive material and by a terminal area on the chip or on a leadframe, wherein the terminal area consists at least partly of the second material.

7. The electric device according to claim 1, wherein the current load and the contact pad are enclosed by a molding compound.

8. The electric device according to claim 1, wherein the contact pad is implemented such that, when the fused eutectic mixture is solidified, the conductive connection between the first and second terminal areas is re-established.

9. The electric device according to claim 1, wherein the first material is aluminum and the second material zinc.

10. The electric device according to claim 1, wherein one of the following eutectic mixtures can form at the contact pad:
82.6 Cs, 17.4 Zn
80 Au, 20 Sn
97.5 Pb, 2.5 Ag
96 Pb, 2.5 Ag
1.5 Sn
88 Au, 12 Ge
96.4 Au, 3.6 Si
95 Zn, 5 Al

11. The electric device according to claim 1, further comprising:
a first current terminal and a second current terminal, wherein the first current terminal and the second current terminal are arranged such that a current through a current load flows through the first current terminal and the second current terminal, wherein a first area between the first current terminal and the contact pad consists of the first material, and a second area between the second current terminal and the contact region consists of the second material.

12. An electric device for temperature-dependent interruption of a current inlet, comprising:
a contact pad in the current inlet or outlet, comprising:
a first terminal area of a first conductive material; and
a second terminal area of a second conductive material differing from the first material,
wherein the first material and the second material are conductively connected at a contact region, wherein the first material and the second material are selected such that they can form an eutectic mixture having a fusion temperature below a fusion temperature of the first and second materials, and which depends on an operating state of the current load to be protected; and
wherein the contact pad is implemented such that a current flow is established through a contact area between the first material and the second material, so that the conductive connection between the first and the second terminal area is interrupted by the occurrence and flow of a fused eutectic mixture.

13. The electric device according to claim 12, wherein the contact area is implemented such that when separating the first and second materials along the contact area, a current between the first terminal area and the second terminal area is interrupted.

14. The electric device according to claim 12, comprising:
a first current terminal and a second current terminal in the current inlet, wherein the first current terminal and the second current terminal are implemented such that a current flows through the first current terminal and the second current terminal, wherein a first area between the first current terminal and the contact pad consists of the first material, and a second area between the second current terminal and the contact region consists of the second material.

15. A method for producing an electric device having a temperature-interrupting current inlet, comprising:
providing a first conductive material;
providing a second conductive material differing from the first material, wherein the first and second materials are selected such that they can form an eutectic mixture having a fusion temperature below the fusion temperature of the first and second materials and depending on an operating state of the current load to be protected; and
producing a contact pad in a current inlet or current outlet of a current load of the device, wherein the contact pad is implemented such that a current flow through a contact area between the first material and the second material is established, so that a conductive connection between a first terminal area of the first conductive material and a second terminal area of the second conductive material is interrupted during the occurrence and flow of a fused eutectic mixture.
